(19) United States
(12) Patent Application Publication
(10) Pub. No.: US 2022/0413042 A1
(43) Pub. Date: Dec. 29, 2022

(54) DEBUG SYSTEM AND DEBUG METHOD

(71) Applicant: XEPIC CORPORATION LIMITED, Nanjing (CN)

(72) Inventors: Tsair-Chin Lin, Saratoga, CA (US); Jingbo Gao, San Jose, CA (US)

(21) Appl. No.: 17/894,677

(22) Filed: Aug. 24, 2022

Related U.S. Application Data
(63) Continuation-in-part of application No. 16/752,167, filed on Jan. 24, 2020.
(60) Provisional application No. 62/797,869, filed on Jan. 28, 2019.

(51) Int. Cl. G01R 31/317; G01R 31/3183

(52) U.S. Cl. CPC G01R 31/31705; G01R 31/318314; G01R 31/31727

(57) ABSTRACT

A debug system for debugging a logic design includes an adaptor and a debug station connected to the adaptor. The logic design includes a plurality of design modules. The adaptor is configured to receive an emulation output of the logic design. The emulation output includes a design snapshot of the logic design and input signals to the logic design that both are recorded during an emulation process of the logic design. The debug station is configured to generate, based on the emulation output and a netlist of a design module of the logic design, an emulation history of the design module.

### CROSS-REFERENCE TO RELATED APPLICATIONS

This application is a continuation-in-part of U.S. application Ser. No. 16/752,167, filed on Jan. 24, 2020, which claims the benefit of U.S. Provisional Patent Application No. 62/797,869, filed Jan. 28, 2019, both of which are incorporated herein by reference in their entireties.

### TECHNICAL FIELD

The present disclosure relates to the field of logic design and, more particularly, to a debug system and a debug method for logic designs.

### BACKGROUND

As the size of a logic design, e.g., an Integrated Circuit (IC) design, grows to hundreds of millions of gates or even billions of gates, emulators have become important tools for completing design verification of the logic design. The design verification process generally includes two stages. The first stage is to verify whether the logic design works correctly in a testing environment. The second stage is to debug the logic design if a problem is found during the first stage. The second stage may usually take much more time than the first stage.

### SUMMARY

In accordance with the disclosure, there is provided a debug system for debugging a logic design including a plurality of design modules. The debug system includes an adaptor and a debug station connected to the adaptor. The adaptor is configured to receive an emulation output of the logic design. The emulation output includes a design snapshot of the logic design and input signals to the logic design that both are recorded during an emulation process of the logic design. The debug station is configured to generate, based on the emulation output and a netlist of a design module of the logic design, an emulation history of the design module.

Also in accordance with the disclosure, there is provided a method for debugging a logic design including a plurality of design modules. The method includes receiving, by a debug system, an emulation output of the logic design, and generating, based on the emulation output and a netlist of a design module of the logic design, an emulation history of the design module. The emulation output includes a design snapshot of the logic design and input signals to the logic design that both are recorded during an emulation process of the logic design.

Also in accordance with the disclosure, there is provided non-transitory computer-readable storage medium storing a computer program, where the computer program is executed by a processor to implement a method for debugging a logic design including a plurality of design modules. The method includes receiving, by a debug system, an emulation output of the logic design, and generating, based on the emulation output and a netlist of a design module of the logic design, an emulation history of the design module. The emulation output includes a design snapshot of the logic design and input signals to the logic design that both are recorded during an emulation process of the logic design.

### DESCRIPTION OF THE DRAWINGS

FIG. 1 schematically shows a design verification process of a logic design using a debug system according to some embodiments of the present disclosure.

FIG. 2 schematically shows a data conversion process according to some embodiments of the present disclosure.

FIG. 3A schematically shows a data conversion process according to some other embodiments of the present disclosure.

FIG. 3B schematically shows a structure for the HDL source code of a replay adaptor according to some embodiments of the present disclosure.

FIG. 4 schematically shows a method for debugging a logic design according to some embodiments of the present disclosure.

FIG. 5 schematically shows a logic design according to some embodiments of the present disclosure.

FIG. 6 schematically shows a process for debugging a logic design according to some embodiments of the present disclosure.

FIG. 7 schematically shows a device for debugging a logic design according to some embodiments of the present disclosure.

### DETAILED DESCRIPTION

Technical solutions of the present disclosure will be described with reference to the drawings, in which the same numbers refer to the same or similar elements unless otherwise specified. It will be appreciated that the described embodiments are some rather than all of the embodiments of the present disclosure. Other embodiments conceived by those having ordinary skills in the art on the basis of the described embodiments without inventive efforts should fall within the scope of the present disclosure.

Unless otherwise defined, all the technical and scientific terms used herein have the same or similar meanings as generally understood by one of ordinary skill in the art. As described herein, the terms used in the specification of the present disclosure are intended to describe example embodiments, instead of limiting the present disclosure. The term “and/or” used herein includes any suitable combination of one or more related items listed.

For large logic designs, e.g., designs with over half billion or multi-billion gates, a hardware-based emulator is an important tool in the design verification process, because software-based simulators usually cannot handle such a big design and may take too long to generate a verification result in a software manner. Emulators usually are used in two stages of the design verification process of a logic design. The first stage, e.g., an emulation process, includes a regression or normal run, where a user employs the emulator to verify whether the logic design is working properly in a certain working environment. The second stage, e.g., a debug process, is a stage where the user uses the emulator to identify the “bugs” or problems of the logic design that are detected during the emulation process, i.e., the first stage. Compared to the emulation process, the debug process does not require high emulation power as needed in the emulation process, but the debug process may usually take much more time than the emulation process.

Because the emulation resources are shared by multiple logic designs to be verified, verification activities of one logic design can affect the verification progress of another logic design. For example, an emulator is occupied for debugging if a problem is found during the emulation process of a logic design, and is thus not available for anther logic design to be verified.

Each Integrated Circuit (IC) design project usually involves a plurality of IC designs, e.g., a plurality of design modules of the IC design project. Because of overlapped demands for the emulation resources, the user may need to wait for the occupied emulation resource to be released. As such, the overall verification time also includes the wait time, and the verification process of the plurality of IC designs is thus time consuming, resulting in low verification efficiency. To shorten the overall verification time for each IC project, an IC design company may need to spend more money to purchase more emulators, thereby increasing operation cost of the company.

Considering the factors discussed above, including verification time, verification efficiency, and the monetary overhead for emulation resources, as well as the increasing logic design size, and shorter and shorter time to market an IC, it is urged to find a solution to the above technical problems.

To simplify description of the present disclosure, hereinafter, an emulator used in the debug process will also be referred to as a “debug station,” to distinguish it over an emulator used during the verification process.

One aspect of the present disclosure provides a debug system including a plurality of debug stations. The debug system enables users to utilize different emulators, e.g., from different vendors and/or different platforms, to run the emulation process and the debug process. As such, users can choose appropriate emulators for miming a design in the emulation process and appropriate emulators (debug stations) for debugging in the debug process. For example, for a same logic design, the emulator used in the emulation process may be different from the emulator (debug station) used in the debug process. According to some embodiments of the present disclose, less expensive emulators rather than expensive full-function emulators that are used in the emulation process, can be provided for the debug process.

The debug system can be a platform-neutral debug system. Unlike the conventional technologies, where people needed to run emulation process and debug process using same emulator from beginning to the end, the mix-and-match or cross-platform method described herein allows users to use emulators in the most efficient and cost-effective way. For example, the user can run the emulation process of the whole logic design on a large emulator, save the results of the emulation process of the logic design, and debug the logic design using a smaller and less expensive emulator (debug station) of the debug system. The emulator for the emulation process and the emulator (debug station) for the debug process can be from different vendors/platforms.

In some embodiments, the debug system can be a cloud-based system. For example, the user does not have to purchase a large number of debug stations, but only needs to lease debug stations as needed. A cloud-based debug system may be a pool of different types of emulators, e.g., machines from different vendors/platforms. Different types of emulators may have different manners of running the emulation process of a same design.

The debug system implements a remapping mechanism to realize the platform-neutral debug system. The remapping mechanism is based on record/register-transfer level (RTL) remapping/playback sequence. The remapping mechanism enables emulation output of an emulator of a vendor/platform to be replayed by an emulator (a debug station) of another vendor/platform. The remapping mechanism also allows a part of the logic design (not the whole logic design), e.g., a design module of the logic design, to be re-run by the debug station. The remapping mechanism can also be applied to a whole logic design. By implementing the remapping mechanism, a debug process of a logic design can be conducted in any debug station in the debug system.

During the debug process, the user can select an appropriate debug station from the poll of debug stations (e.g., the debug system), and run the debug process using the selected debug station. As such, the cloud-based debug system can facilitate today's global-based design activities. For example, the cloud-based debug system enables verification of a design by a team, of which the team members are in geographically diversified locations.

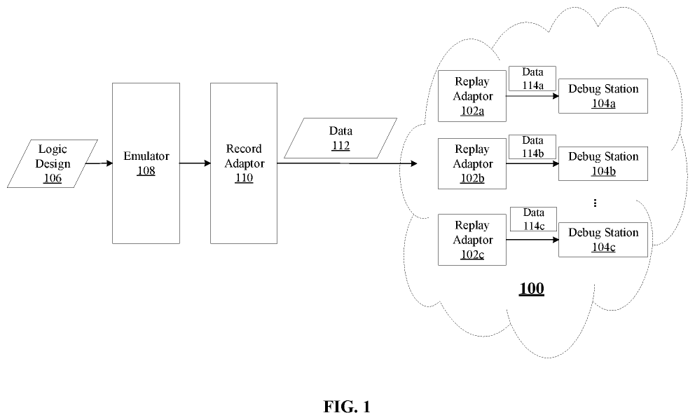

FIG. 1 schematically shows a design verification process of a logic design using a debug system 100 according to some embodiments of the present disclosure. As shown in FIG. 1, the debug system 100 includes a plurality of replay adaptors 102, e.g., 102a-102c, and a plurality of debug stations 104, e.g., 104a-104c, corresponding to the plurality of replay adaptors 102a-102c, respectively. The plurality of debug stations 104, e.g., 104a-104c, may be from a same vendor/platform, or some or all of them may be from different vendors/platforms. FIG. 1 shows the debug system 100 including three replay adaptors 102a-102c and three debug stations 104a-104c as an example. The debug system 100 can include more or less reply adaptors and/or more or less debug stations. For example, in some embodiments, the debug system 100 may include only one replay adaptor 102 that is coupled with the plurality of debug stations 104a-104c. The one adaptor can, for example, be actively linked to only one of the plurality of debug stations 104a-104c at a time.

As shown in FIG. 1, a logic design 106 is verified by an emulator 108 in the emulation process (first stage). During the emulation process, a record adaptor 110 captures data 112 from the emulator 108. The data 112 can also be referred to as an emulation history. The data 112 can include design snapshots of a specified module to be debugged. The design snapshot may include values of state elements of the logic design 106. The state elements may be logic units of the logic design 106 including, e.g., flip-flop logic units (flip-flops), latch logic units (latches), and/or memory logic units (memories). An initial design snapshot may be saved at the beginning of the emulation process, recording initial values of the logic units of the logic design 106. During the recording, one or more design snapshots can be saved. When a design snapshot is being saved, the clock of the logic design 106 can be paused, so that the state of the logic design 106 does not change and values of the state elements can be saved during the paused period. Therefore, a design snapshot can be associated with a given clock (also known as a time sequence). Accordingly, during replay, one design snapshot can be restored depending on a time sequence that the user desires to start the replay. A plurality of design snapshots may also be recorded at certain time intervals during the emulation process. A design snapshot may be a snapshot of a whole logic design 106, or a snapshot of a part of the logic design 106, e.g., a design module of the logic design 106. The design snapshot can include values of state elements, such as flip-flops, latches, and memories. The record adaptor 110 sends the captured data 112 to the replay adaptor 102, which then restores the data 112 for one of the debug stations 104a-104c to replay.

The record adaptor 110 can perform the recording in the emulator 108.

The record adaptor 110 can receive waveforms and clock information of the emulation process from the emulator 108. The waveforms can describe signal behaviors for signals of a logic design over a period of time. The clock information can describe how clocks are transformed in the emulator 108. The record adaptor 110 can invoke a TransformClockShape procedure to adjust the waveforms based on the clock information. The adjustment of the waveforms can generate platform-neutral waveforms for input stimulus.

The record adaptor 110 can be implemented using an “instrumentation logic,” which is an additional logic inserted to the original logic design. For example, the instrumentation logic can be implemented using an FPGA on the emulator 108 or a debug station 104. Thus, during the record phase, the instrumentation logic of the record adaptor 110 can automatically record the information needed for debug station operations.

The record adaptor 110 can also be configured to map the name of state elements (e.g., flip-flops, latches, and memories) and input pins of a logic design (e.g., a whole design or a design module) to the internal representations of the state elements and input pins inside the emulator 108. During the record phase, the record adaptor 110 can use those internal representations to acquire values of the state elements and input pins from the emulator 108. In some embodiments, the state elements of the logic design can be referred to as circuits of the logic design.

The record adaptor 110 can also be configured to retrieve the current simulation time on the emulator 108. The record adaptor 110 can also be configured to adjust a timestamp according to the method of how clocks are transformed in the emulator 108.

The record adaptor 110 can also be configured to upload the current values for instances of flip-flops, latches, and memories to the host machine and eventually to the cloud system (e.g., debug stations).

The record adaptor 110 can also be configured to store input stimulus data from the emulator 108 to the host machine and eventually to the cloud system (e.g., debug stations).

The record adaptor 110 can be configured to intercept user actions for force, release, and memory load as part of the data 112. These actions typically are issued via a command interface of an emulation runtime system (e.g., the emulator 108). The command interface can record activities, such as the force/release activities, in runtime log. These activities can be retrieved from the log file.

Therefore, in addition to the design snapshot, the data 112 can further include values of input pins of the specified module to be debugged. The input pins can be recorded cycle by cycle. When a user wants to record the whole design, the input pins are the top level input of the design. When a user wants to record a certain design module, the input pins are for the specified design module. In some embodiments, values of the input pins can be stored as a waveform file, which can be compressed and processed by typical EDA tools. For example, a format of the waveform file can be VCD, FSDB or SHM.

In some embodiments, the data 112 can also include user actions performed on the specified design module to be debugged. When a user runs an emulation of the logic design 106, the user may want to perform some actions on the specific design module. Those actions can be recorded so that the user can re-apply those actions during the replay phase. Typical actions can include a “force” type action, a “release” type action, a “memory load” type action, or the like.

The “force” type action can stick a signal to a fixed value, regardless of what value it should have based on HDL behavior. As such, the “force” type action can allow the user to observe the behavior of the design module under the forced signal being applied to the design module.

The “release” type action can cancel the effect of the “force” type action. For example, the forced signal can be canceled and start to behave according to the HDL description of the logic design 106.

The “memory load” type action can load data to a memory through a backdoor. It is appreciated that data in the memory can be inputs to many logic units of the design module. As such, the “memory load” type action can affect the behavior of the design module in the upcoming time sequences.

It is appreciated that the above three actions are merely exemplary, and more actions can be recorded in the data 112.

While saving a user action in the data 112, a time stamp for identifying when the user action happened can be saved. Therefore, the action is able to be re-applied to the design model at the exact time point during the replay phase. This involves the user clock to be paused when the user action happened.

The data 112 can be saved in sessions. A session can be a set of data which is saved within a time range during the record phase. The sessions can be associated with session database for storing the data 112.

It is appreciated that the data 112 captured at the record adaptor is emulator-characterized. In other words, before the data 112 can be replayed at a debug station, the data 112 needs to be processed and converted into platform-neutral data 114a-114c.

The data 112 can be transmitted to relay adaptor 102a-102c as shown in FIG. 1.

Relay adaptors 102a-102c can be configured to convert emulator-characterized data 112 captured at the record adaptor 110 into platform-neutral data, and send the platform-neutral data 114a-114c to debug stations 104a-104c.

Provided the formats of data recorded by known emulators, relay adaptors 102a-102c can map elements of the data 112 to data 114a-114c, according to mapping relationships between the emulator 108 and each of the debug stations 104a-104c. The emulator 108 can be from a first vendor, and the debug station 104a-104c can be from a second vendor. The mapping relationships can be determined based on the emulator 108 and the debug stations 104a-104c. It is appreciated that the debug stations 104a-104c can be from different vendors, and the mapping relationships can be determined separately. For example, the debug station 104a is from a first vendor and the debug station 104b is from a second vendor.

In some embodiments, the record adaptor 110 and the replay adaptor 102 can be implemented via an instrumentation logic, which may be an additional logic inserted to original design by the emulator 108 and/or the debug station 104, respectively. For example, the instrumentation logic can be realized using a field-programmable gate array (FPGA) on the emulator 108 and/or the debug station 104. During the emulation process of the design, the instrumentation logic can automatically record data needed for debug station operations during a record phase, and replay the whole design or the design module to be debugged during a replay phase. The record phase can also be referred to as a test phase, and the replay phase can also be referred to as a debug phase.

It is appreciated that, in some embodiments, the record adaptor 110 and the replay adaptor 102 can be implemented as a single adaptor. The single adaptor can receive an emulation output of the logic design generated by an emulator (e.g., emulator 108 of FIG. 1) during an emulation process. The emulation output can include a design snapshot of the logic design and input signals to the logic design that both are recorded during the emulation process. A debug station can be connected to the single adaptor and configured to generate, based on the emulation output and a netlist of a design module of the logic design, an emulation history of the design module.

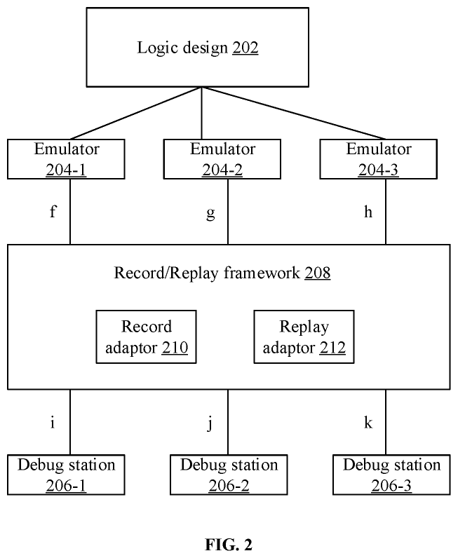

To further illustrate the process of conversion of platform-neural data, FIG. 2 schematically shows a data conversion process according to some embodiments of the present disclosure. As shown in FIG. 2, a user may choose one or more emulators of three emulators 204-1, 204-2, and 204-3 of different types for the record process (the record phase) of a logic design 202.

In the record process, the three emulators 204-1, 204-2, and 204-3 may be from different vendors, and run emulation in three different manners to generate emulation results using three different transformation functions, f, g, and h, respectively. Through a record/replay framework 208 including a record adaptor 210 and a replay adaptor 212, the emulation results can be recorded and converted based on transformation functions i, j, and k corresponding to the three emulators 204-1, 204-2, and 204-3, respectively, to obtain recorded emulation results. The recorded emulation results can be then sent to corresponding debug stations 206-1, 206-2, and 206-3 for debugging in the replay phase. The transformation functions i, j, and k match the transformation functions of the three debug stations 206-1, 206-2, and 206-3, respectively. As such, the user can select one or more of the debug stations 206-1, 206-2, and 206-3 to replay the recorded emulation results in the replay process (e.g., replay phase). A debug system including the record/replay framework 208 and the debug station (e.g., debug stations 206-1, 206-2, or 206-3) can be a platform-neutral debug system.

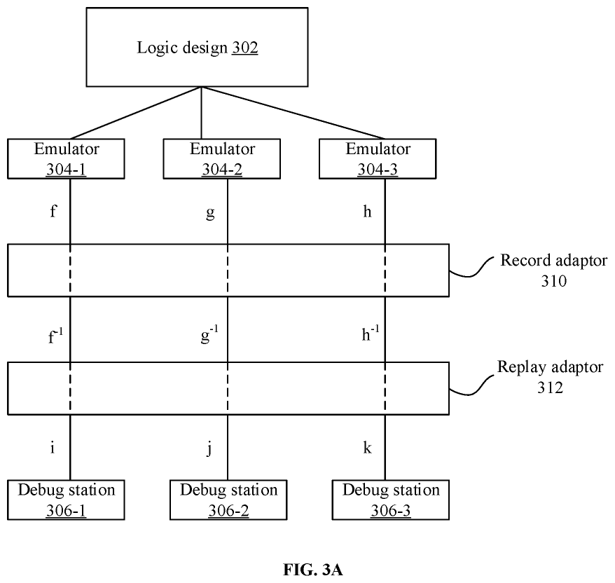

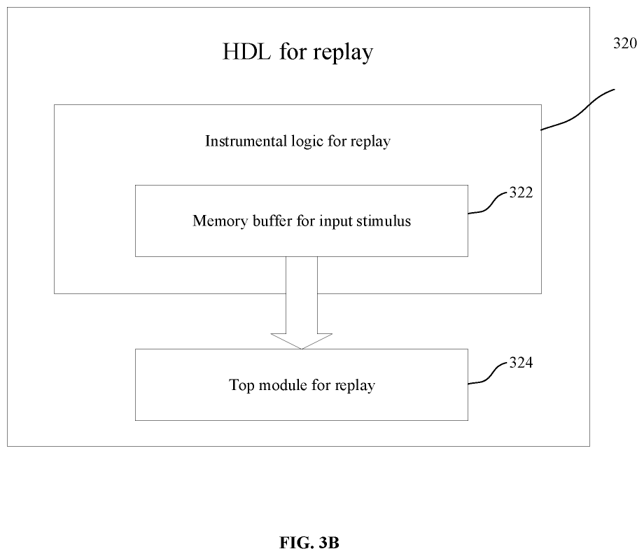

In some embodiments, the emulation results may be converted more than once, such as twice, to match the transformation function of the corresponding debug station. For example, FIG. 3A schematically shows a data conversion process according to some other embodiments of the present disclosure. As shown in FIG. 3A, the user can select one or more emulators from three emulators 304-1, 304-2, and 304-3 of different types to verify a logic design 302 in the emulation process (e.g., the test phase). The three emulators 304-1, 304-2, and 304-3 may be from different vendors/platforms, and run emulation in three different manners to generate emulation results, which are characterized by three different transformation functions, f, g, and h, respectively. It is appreciated that the transformation functions reflect characteristics of the emulators 304-1, 304-2, and 304-3, and can be integrated as part of the emulators 304-1, 304-2, and 304-3.

As discussed above, a design snapshot may be associated with a part of the logic design 106, and a plurality of design snapshots can be recorded. Thus, each of the three emulators 304-1, 304-2, and 304-3 can be configured to generate three different emulation results for generating three design snapshots using a record adaptor.

As shown in FIG. 3A, a record adaptor 310 can convert the emulation results using inversion-transformation functions, f⁻¹, g⁻¹, and h⁻¹ corresponding to the emulators 304-1, 304-2, and 304-3, to generate converted emulation results as the record results. Unlike the transformation functions reflecting characteristics of the emulators from different vendors, the inversion-transformation functions aim to remove the characteristics of the emulators, so that the converted emulation results can be platform-neutral record results. The emulation results may be presented in waveform and the record results can be platform-neutral waveform. The inverse-transformation functions, f⁻¹, g⁻¹, and h⁻¹ correspond to the three different transformation functions f, g, and h, of the three different types of emulators 304-1, 304-2, and 304-3, respectively.

The platform-neutral record results can be sent to debug stations, and played at the debug stations. The debug station can include a replay adaptor for processing the platform-neutral record results before the debug station can replay the record results.

As also shown in FIG. 3A, a replay adaptor 312 can convert the record results (e.g., data 112) using transformation functions, i, j, and k, to generate converted record results as the replay results to be sent to three debug stations 306-1, 306-2, and 306-3 of different types for debugging. The transformation functions, i, j, and k match the transformation functions of the three different types of debug stations 306-1, 306-2, and 306-3, respectively. As such, the user can select anyone of the debug stations 306-1, 306-2, and 306-3 to run the replay results in the debug process.

In some embodiments, the record adaptor 310 and the replay adaptor 312 may be combined into one adaptor, which is configured to convert the emulation results to match the transformation function of a corresponding debug station 306.

In some embodiments, the replay adaptor 312 can be implemented using an instrumentation logic, which can be part of the FPGA of the debug station.

FIG. 3B illustrates a structure for the HDL source code of a replay adaptor according to some embodiments of the present disclosure. The replay adaptor of FIG. 3B can be the replay adaptor 312, and implemented by an instrumentation logic 320. There is a memory buffer 322 to hold data for input stimulus. The input stimulus can be, for example, the captured data 112. This memory buffer 322 is controlled by instrumentation logic 320, which maintains a read address for the memory buffer 322. The read address can be increased by 1 on each cycle, so that in each cycle, a new set of input stimulus data (e.g., the captured data 112) will be read out from the memory buffer 322. The read-out data can drive input pins on the top module for replay 324. The top module can be a whole design of the logic design 106 or a design module selected by the user during recording. In some embodiments, the memory buffer 322 has a certain depth. During replay, an initial set of input stimulus data are loaded into the memory buffer 322. Then, the replay runs for a certain number of cycles until all the data is used. Then, a new set of input stimulus data is loaded and replay runs more cycles.

Back to FIG. 3A, in some embodiments, the replay adaptor 312 can be configured to activate emulation replay at a debug station (e.g., debug station 306-1, 306-2, or 306-3). In other words, procedures in the replay adaptor 312 may include sending out emulation data and instructions to cause the debug station to generate an emulation history as instructed by the replay adaptor 312.

To start a replay, a user can specify a session database and a time range for the replay.

As discussed above, the replay adaptor 312 can convert the data 112 using transformation functions, i, j, and k, to generate converted record results as the replay results to be sent to three debug stations 306-1, 306-2, and 306-3. The converted record results can be platform-neutral.

In some embodiments, the replay adaptor 312 can provide an interface to receive the data 112 from the record adaptor. The replay adaptor 312 can get the information about how clocks are transformed in the emulator, and map names of state elements and input pins of a logic design to the internal representations of the logic design inside the emulator. During the replay, the replay adaptor 312 can use those internal representation to set values into the debug station. The replay adaptor 312 can preserve state elements corresponding to the logic design to be replayed during the compilation of the logic design. As discussed above, the state elements can be mapped to internal representations. Then, the replay adaptor 312 can set values for instances of flip-flops, latches, and memories of the logic design according to a selected time point within the time range using the internal representations, and therefore, the state of the logic design at the debug station can be replayed to the selected time point.

In addition, the replay adaptor 312 can download cycle-by-cycle data for input pins of the logic design into a stimulus buffer of the debug station, and thus, the debug station can continue to execute the emulation of the logic design from the selected time point. Then, the replay adaptor 312 can instruct the debug station to run the emulation until a given time stamp is met or a trigger happens. It is appreciated that the data 112 also includes user actions that are applied to the logic design during the emulation. Therefore, the replay adaptor 312 can extract the user actions applied during the emulation, and apply the extracted user actions to the debug station during the replay.

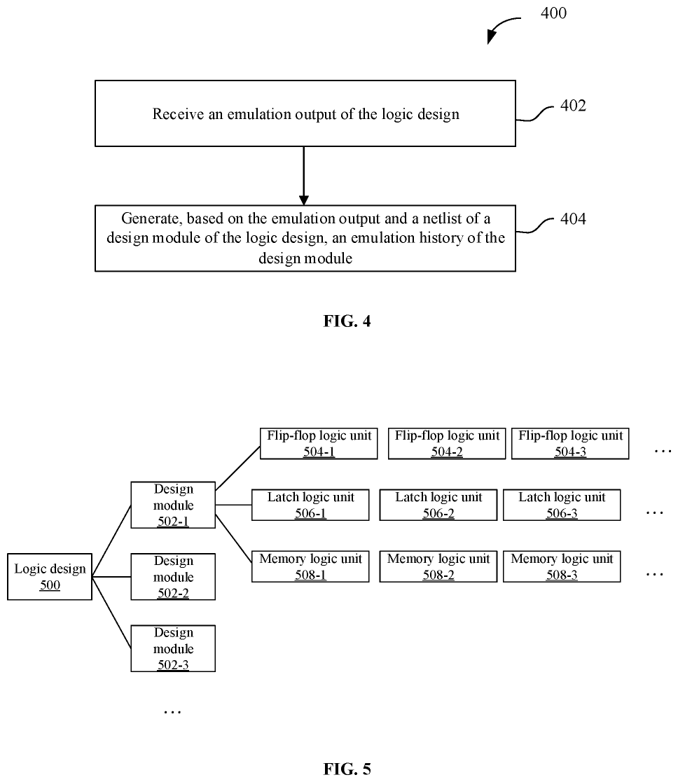

Another aspect of the present disclosure provides a method for debugging a logic design. FIG. 4 schematically shows a method 400 for debugging a logic design according to some embodiments of the present disclosure. As shown in FIG. 4, the method 400 includes receiving an emulation output of a logic design (402), and generating, based on the emulation output and a netlist of a design module of the logic design, an emulation history of the design module (404).

The emulation output may include a design snapshot of the logic design and input signals to the logic design that both are recorded during an emulation process of the logic design. The emulation output is generated by an emulator during the emulation process. The emulator can be, for example, remotely connected to the debug system.

The method 400 may be implemented by a debug system including an adaptor and a plurality of debug stations. The adaptor may be configured to receive the emulation output, and one or more of the plurality of debug stations may be configured to generate, based on the emulation output and the netlist of the design module of the logic design, the emulation history of the design module. In some embodiments, the adaptor can include a record adaptor and a replay adaptor.

In some embodiments, the adaptor may be further configured to adjust the emulation output based on information of the emulator, and the debug station is further configured to generate, based on the adjusted emulation output and the netlist of the design module, the emulation history of the design module. The adjusted emulation output can be platform-neutral. The information of the emulator can include clock information, the clock information can describe how clocks are transformed in the emulator. The information can also include mapping relationships for mapping the name of state elements (e.g., flip-flops, latches, and memories) and input pins of a logic design (e.g., a whole design or a design module) to the internal representations of the state elements and input pins inside the emulator.

In some embodiments the adaptor may be further configured to select, based on a start time of replay, a design snapshot from the data recorded during the emulation process. In some embodiments, the start time of replay may be determined based on an input of the user. For example, the user may specify the start time of replay. In some embodiments, only one design snapshot is saved during a recording session close to the start time of replay. The adaptor may be configured to select the one design snapshot. In some embodiments, more than one design snapshots are saved in respective session databases during each recording session. The adaptor may be configured to select a design snapshot that is before the start time of replay and is closest to the start time of replay.

In some embodiments, the debug system includes one adaptor and a plurality of debug stations, where the adaptor is configured to be actively linked to only one of the plurality of debug stations at one time. In some other embodiments, the debug system includes a plurality of debug stations and a plurality of adaptors connected to the plurality of debugs stations, respectively.

In some embodiments, the logic design may include one or more design modules and each of the one or more design modules may include one or more logic units. The one or more logic units may be of a same type or of different types. For example, as shown in FIG. 5, a logic design 500 includes a plurality of design modules 502-1, 502-2, 502-3, . . . , and the design module 502-1 includes a plurality of flip-flop logic units 504-1, 504-2, 504-3, . . . , a plurality of latch logic units 506-1, 506-2, 506-3, . . . , and a plurality of memory logic units 508-1, 508-2, 508-3, . . . .

In some embodiments, the emulation output includes the design snapshots and the input signals recorded during the emulation process, in which the logic design is verified by an emulator. The data recorded may be saved in a session database.

In some embodiments, the design snapshots include an initial design snapshot captured at the beginning. For example, the beginning (“beginning point”) may refer to a time point after the emulation starts. In some embodiments, the design snapshots may further include a plurality of design snapshots recorded at different time points separated by certain intervals while the logic design is running in the emulator. One or more design snapshots may be saved during each recording session. When a design snapshot is being saved, the clock of the logic design may be paused so that the state of the design does not change. A design snapshot may include a set of values associated with one or more state elements of the logic design. The state elements include at least one of flip-flop logic units, latch logic units, or memory logic units.

In some embodiments, a design snapshot may be a snapshot of a whole logic design. In some embodiments, a design snapshot may be a snapshot of a part of the logic design, e.g., a design module of the logic design. Whether a design snapshot is a snapshot of a whole logic design and/or a part of the logic design can be determined based on an input of the user.

The input signals may include input signals of the whole logic design and/or input signals of a specific design module of the logic design. For example, when a user instructs to record the whole logic design, the input pins are the top-level input of the logic design. When the user instructs to record a certain design module, the input pins are for the specified design module. Input signals of the input pins can be recorded in a cycle-by-cycle manner. A cycle may be a clock cycle. The period of time of each cycle may be the time between edges of a clock signal. The recorded input signals, e.g., cycle-by-cycle data, may be equivalent to a waveform. A file format of the input signals may include VCD, FSDB, or SHM. In some embodiments, the input signals are not necessarily recorded in every cycle. For example, the input signals of a cycle may not be recorded if there is no value change on the input pins in this cycle.

The netlist of the design module may include a structure of circuits of the design module and connection relationships among the circuits of the design module. The netlist may be a gate-level netlist. The gate-level netlist may include a structure of gate-level circuits (e.g., gates) in the design module and connection relationships among the gate-level circuits in the design module. In some embodiments, the debug station may be configured to obtain the netlist based on the design snapshot. In some other embodiments, the debug station may be configured to obtain the netlist based on an input of the user. A netlist of the whole logic design may include a structure of all the circuits of the whole logic design and connection relationship among the circuits of the whole logic design.

User actions may also be recorded during the emulation process. The user actions may include Force, Release, and/or Memory Load actions. When the user action is saved in a recording session, a timestamp to identify when the action happened is also saved, and the clock may be paused automatically.

The clock signals may also be recorded during the emulation process. The clock signals are associated with the design snapshot, the input signals, and the user actions. For example, the clock signals can indicate timestamps and/or time sequences of each of the design snapshots, input signals, and/or user actions.

In some embodiments, the emulator is configured to record the design snapshots, input signals, user actions, and/or clock signals of the logic design during the emulation process.

In some embodiments, an adaptor, e.g., the record adaptor, may be configured to map names of state elements and input pins to internal representations used by the emulator. The record adaptor may be further configured to acquire values of those internal representations from the emulator.

In some embodiments, the record adaptor may be configured to retrieve a current simulation time from the emulator. The record adaptor may be configured to upload current values for flip-flops, latches, and memories to a debug system. The record adaptor may be configured to upload input signals from the emulator to the debug system.

The record adaptor may be further configured to retrieve clock information about how clock signals are transformed by the emulator, and adjust clock signals according to this clock information.

In some embodiments, an adaptor, e.g., the replay adaptor, may be configured to select, based on a start time point of replay, a design snapshot from the data recorded during the emulation process. In some embodiments, the start time point of replay may be determined based on an input of the user. For example, the user may specify the start time point of replay. In some embodiments, only one design snapshot is saved during a recording session close to the start time point of replay. The replay adaptor may be configured to select the one design snapshot. In some embodiments, more than one design snapshots are saved during each recording session. The replay adaptor may be configured to select a design snapshot that is before the start time point of replay and is closest to the start time point of replay.

The replay adaptor may be further configured to download input signals, e.g., cycle by cycle data of input pins, into a stimulus buffer of a debug station. The replay adaptor may be further configured to set up a read address for the stimulus buffer.

The debug station is configured to apply input signals to the selected design snapshot while running the selected design snapshot, and the debug station can generate an emulation history accordingly. For example, while the debug station is running the selected design snapshot, the debug station can apply the input signals to the design module cycle by cycle to generate the emulation history of the design module cycle by cycle, which may be a loop process. The design module may be a design module to be debugged. The debug station may apply the input signals based on the clock signals.

The debug station may be further configured to apply user actions while running the selected design snapshot. For example, the debug station may be configured to apply a user action at the current cycle. The user actions may include Force action, Release action, and/or Memory Load action. The debug station may apply the user actions based on the clock signals.

The debug station may be further configured to set values for the circuits of the netlists of the design module based on the emulation history. For example, the debug station may set values for flip-flops, latches, and/or memories of the design module based on the emulation history. The debug station may be configured to run the emulation for debug until a specified timestamp is met or until a trigger event occurs.

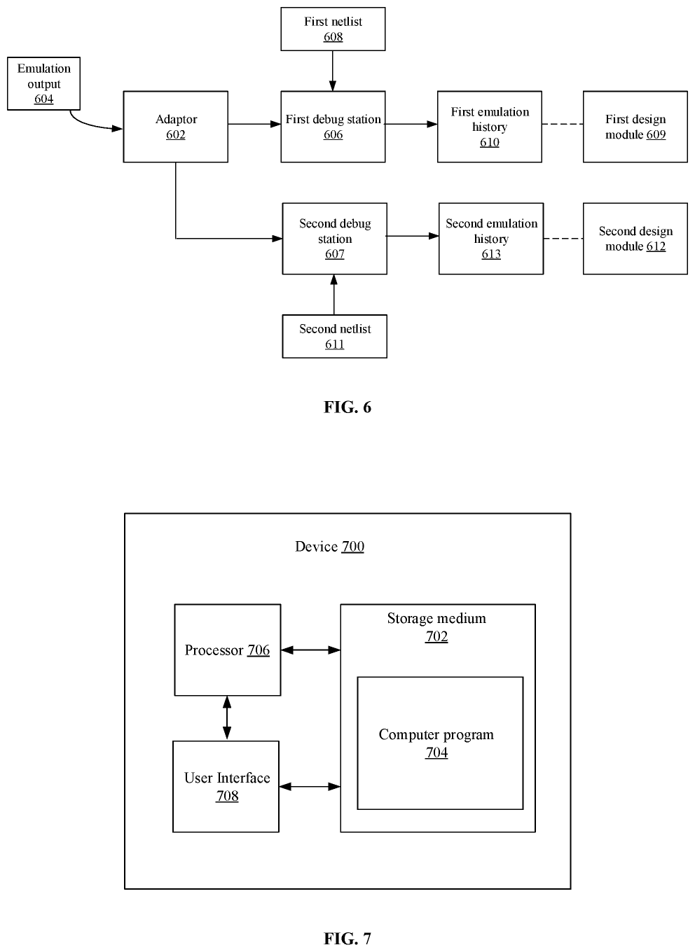

FIG. 6 schematically shows a process for debugging a logic design according to some embodiments of the present disclosure. As shown in FIG. 6, an adaptor 602 receives from an emulator an emulation output 604 of a logic design that includes a plurality of design modules, and forwards the emulation output 604 to a first debug station 606 and a second debug station 607 of a debug system. The first debug station 606 further receives a first design netlist 608 of a first design module 609 of the logic design, and generates a first emulation history 610 based on the emulation output 604 and the first netlist 608. The first emulation history 610 is used for debugging the first design module 609. The second debug station 607 further receives a second netlist 611 of a second design module 612 of the logic design, and generates a second emulation history 613 based on the emulation output 604 and the second netlist 611. The second emulation history 613 is used for debugging the second design module 612. The debugging process of the first design module 609 by the first debug station 606 may be independent from the debugging process of the second design module 612 by the second debug station 607. For example, the debugging processes of the first design module 609 and the second design module 612 of the same logic design can be performed in parallel.

In some embodiments, the first debug station 606 utilizes a transformation function different from that used by the second debug station 607. For example, the first debug station 606 and the second debug station 607 may be from different vendors/platforms. The debug system including the first debug station 606 and the second debug station 607 is a platform-neutral debug system.

The debug system of the present disclosure enables the mix-and-match or cross-platform selection of the emulators, allowing users to choose the appropriate emulators for the emulation process and the debug process, respectively, thereby improving the utilization efficiency of emulation resources.

Another aspect of the preset disclosure provides a device for implementing the methods consistent with embodiments of the present disclosure. FIG. 7 schematically shows a device 700 for debugging a logic design according to some embodiments of the present disclosure. The device 700 may be a platform for managing a debug system. The debug system may include a plurality of debug stations and one or more adaptors. The plurality of debug stations may be from same vendor/platform or from different vendors/platforms.

The device 700 includes a storage medium 702 storing a computer program 704. The storage medium 702 can be any medium, such as a non-transitory computer-readable storage medium, that can store program codes, and can include, for example, a USB disk, a mobile hard disk, a read-only memory (ROM), a random-access memory (RAM), a magnetic disk, or an optical disk.

The device further includes a processor 706. The computer program stored in the storage medium 702 can include instructions that can enable the processor 706 to perform a method consistent with the present disclosure, such as one of the example methods described above, or a part of the method. For example, the instructions can cause the processor 706 to receive an emulation output of a logic design, and generate, based on the emulation output and a netlist of a design module of the logic design, an emulation history of the design module. The emulation output may include a design snapshot of the logic design and input signals to the logic design that both are recorded during an emulation process of the logic design. The emulation output is generated by an emulator during the emulation process, and the emulator can be remotely connected to the debug system.

The device 700 may be remotely connected to the plurality of debug stations of the debug system, e.g., wirelessly.

In some embodiments, as shown in FIG. 7, the device 700 further includes a user interface 708, which can be configured to receive an instruction form a user to select a specific debug station from the plurality of debug stations. In some other embodiments, the processor 706 may be configured to determine a debug station from the plurality of debug stations based on information of the logic design or the design module to be debugged.

In some embodiments, the device 700 may be remotely coupled to one or more emulators to receive emulation output. In some embodiment, a user may input the emulation output to the device 700 via the user interface 708.

In some embodiments, the processor 706 may be configured to receive the emulation output and transmit the received emulation output to the selected debug station. In some other embodiments, the processor 706 may control the selected debug station to establish a communication with the emulator to receive the emulation output.

In some embodiments, the user may input a start time point of replay through the user interface 708. The processor 706 may select the design snapshot from the emulation output based on the start time point of replay.

The debug system may be a cloud-based debug system. For example, the user does not have to purchase a number of debug stations, but to lease debug stations as needed. The device 700 may also act as a platform to lease one or more debug stations as needed from the plurality of debug stations of the debug system, allowing users to use emulators in the most efficient and cost-effective way.

For simplification purposes, detailed descriptions of the operations of device and units are omitted, and references can be made to the descriptions of the method embodiments.

The disclosed device and methods may be implemented in other manners not described here. The methods and devices described above are merely illustrative. For example, multiple elements or components may be combined or may be integrated into another system, or some features may be ignored, or not executed. Further, the coupling or direct coupling or communication connection shown or discussed may include a direct connection or an indirect connection or communication connection through one or more interfaces, devices, or units, which may be electrical, mechanical, or in other form.

The elements described as separate components may or may not be physically separate. That is, the units may be located in one place or may be distributed over a plurality of network elements. Some or all of the components may be selected according to the actual needs to achieve the object of the present disclosure.

In addition, the functional units in the various embodiments of the present disclosure may be integrated in one processing unit, or each unit may be an individual physically unit, or two or more units may be integrated in one unit.

A method consistent with the disclosure can be implemented in the form of computer program stored in a non-transitory computer-readable storage medium, which can be sold or used as a standalone product. The computer program can include instructions that enable a computer device, such as a personal computer, a server, or a network device, to perform part or all of a method consistent with the disclosure, such as one of the example methods described above. The storage medium can be any medium that can store program codes, for example, a USB disk, a mobile hard disk, a read-only memory (ROM), a random-access memory (RAM), a magnetic disk, or an optical disk.

Other embodiments of the disclosure will be apparent to those skilled in the art from consideration of the specification and practice of the embodiments disclosed herein. It is intended that the specification and examples be considered as exemplary only and not to limit the scope of the disclosure, with a true scope and spirit of the invention being indicated by the following claims.

What is claimed is:

1. A debug system for debugging a logic design including a plurality of design modules, comprising:
an adaptor configured to receive an emulation output of the logic design, the emulation output being generated by an emulator during an emulation process and including a design snapshot of the logic design and input signals to the logic design that both are recorded during the emulation process; and
a debug station connected to the adaptor and configured to generate, based on the emulation output and a netlist of a design module of the logic design, an emulation history of the design module.

2. The debug system of claim 1, wherein the design snapshot comprises values of state elements of the logical design at a given time point.

3. The debug system of claim 1, wherein the design snapshot is saved at a time point no later than a given time point and is closest to the given time point among a plurality of design snapshots recorded during the emulation process.

4. The debug system of claim 1, wherein the emulation output further comprises user actions to the logical design during the emulation process.

5. The debug system of claim 4, wherein the user actions comprise at least one of forcing a signal to a value, releasing the value forced to the signal, or loading data of the logical design to a memory.

6. The debug system of claim 4, wherein the design snapshot, the input signals, and the user actions are associated with clock signals.

7. The debug system of claim 6, wherein the debug station is further configured to generate the emulation history of the design module by:
running the design snapshot;
applying the input signals to the design snapshot according to the clock signals; and
applying the user actions to the design snapshot according to the clock signals.

8. The debug system of claim 1, wherein the netlist of the design module comprises a structure of circuits of the design module.

9. The debug system of claim 8, wherein the debug station is further configured to set values for the circuits of the netlist of the design module according to the design snapshot.

10. The debug system of claim 9, wherein the circuits include at least one of a flip-flop, a latch, or a memory.

11. The debug system of claim 1, wherein:
the adaptor is further configured to adjust the emulation output based on information of the emulator to obtain adjusted emulation output; and
the debug station is further configured to generate, based on the adjusted emulation output and the netlist of the design module, the emulation history of the design module, wherein the adjusted emulation output is platform-neutral.

12. The debug system of claim 11, wherein:
the information of the emulator includes clock information of the emulator, wherein the clock information describes how clocks are transformed in the emulator;
the emulation output further includes clock signals; and
the adaptor is further configured to adjust the clock signals based on the clock information.

13. The debug system of claim 11, wherein the adaptor comprises a record adaptor and a replay adaptor, the record adaptor is configured to receive the emulation output of the logic design from the emulator and adjust the emulation output based on information of the emulator to obtain adjusted emulation output, and the replay adaptor is configured to cause the debug station to generate the emulation history of the design module according to the adjusted emulation output.

14. The debug system of claim 1,
wherein the debug station is a first debug station, and the design module is a first design module;
the debug system further comprising:
a second debug station connected to the adaptor and configured to generate, based on the emulation output and a netlist of a second design module of the logic design, an emulation history of the second design module.

15. The debug system of claim 14, wherein the first debug station is from a first vendor and the second debug station is from a second vendor.

16. A method for debugging a logic design including a plurality of design modules, comprising:
receiving, by a debug system, an emulation output of the logic design, the emulation output being generated by an emulator during an emulation process and including a design snapshot of the logic design and input signals to the logic design that both are recorded during the emulation process; and
generating, based on the emulation output and a netlist of a design module of the logic design, an emulation history of the design module.

17. The method of claim 16, wherein:
the emulation output further comprises user actions to the logical design during the emulation process, and
the design snapshot, the input signals, and the user actions are associated with clock signals.

18. The method of claim 17, wherein generating the emulation history comprises:
running the design snapshot;
applying the input signals to the design snapshot according to the clock signals; and
applying the user actions to the design snapshot according to the clock signals.

19. The method of claim 17, wherein the user actions comprise at least one of forcing a signal to a value, releasing the value forced to the signal, or loading data of the logical design to a memory.

20. A non-transitory computer-readable storage medium storing a computer program, wherein the computer program is executed by a processor to implement a method for debugging a logic design including a plurality of design modules, the method including:
receiving, by a debug system, an emulation output of the logic design, the emulation output being generated by an emulator during an emulation process and including a design snapshot of the logic design and input signals to the logic design that both are recorded during the emulation process; and
generating, based on the emulation output and a netlist of a design module of the logic design, an emulation history of the design module.
